(19) United States
(12) Patent Application Publication
(10) Pub. No.: US 2009/0152605 A1
(43) Pub. Date: Jun. 18, 2009

(54) IMAGE SENSOR AND CMOS IMAGE SENSOR

(75) Inventors: Toshikazu Ohno, Mizuho-shi (JP); Yugo Nose, Anpachi-gun (JP); Ryu Shimizu, Mizuho-shi (JP); Mamoru Arimoto, Ogaki-shi (JP); Tatsushi Ohyama, Ogaki-shi (JP)

Correspondence Address: DITTHAVONG MORI & STEINER, P.C., 918 Prince St., Alexandria, VA, 22314, US

(73) Assignee: Sanyo Electric Co., Ltd., Anpachi-Gun (JP)

(21) Appl. No.: 12/338,001

(22) Filed: Dec. 18, 2008

(30) Foreign Application Priority Data
Dec. 18, 2007 (JP) JP2007-325635
Jul. 31, 2008 (JP) JP2008-197220

(51) Int. Cl. H01L 33/00; H01L 27/146

(52) U.S. Cl. 257/294; 257/432; 257/E33.067; 257/E27.133

(57) ABSTRACT

An image sensor includes a carrier generating portion having a photoelectric conversion function, a voltage conversion portion for converting signal charges to a voltage, a charge increasing portion for increasing carriers generated by the carrier generating portion and a light shielding film formed to cover at least one part of the charge increasing portion.

### CROSS-REFERENCE TO RELATED APPLICATIONS

The priority application number JP2007-325635, Image Sensor, Dec. 18, 2007, Toshikazu Ohno, Tatsushi Ohyama, Mamoru Arimoto, Ryu Shimizu, JP2008-197220, Image Sensor, Jul. 31, 2008, Toshikazu Ohno, Yugo Nose, Ryu Shimizu, Mamoru Arimoto, Tatsushi Ohyama, upon which this patent application is based is hereby incorporated by reference.

### BACKGROUND OF THE INVENTION

1. Field of the Invention

The present invention relates to an image sensor and a CMOS image sensor, and more particularly, it relates to an image sensor and a CMOS image sensor each comprising a charge increasing portion for increasing the number of signal charges.

2. Description of the Background Art

An image sensor (CMOS image sensor) comprising a charge increasing portion for increasing the number of signal charges is known in general.

In general, there is disclosed an image sensor (CMOS image sensor) comprising a photodiode portion for storing electrons generated by photoelectric conversion, having a photoelectric conversion function, a multiplier gate electrode applying an electric field for multiplying (increasing) electrons due to impact ionization by an electric field and a transfer gate electrode for transferring the electrons, provided between the photodiode portion and the multiplier gate electrode.

The conventional image sensor is suitable for a product employed under environment of small quantity of light such as a security camera and a dark field camera, and increase in the speed of a shutter is desirable in order to take a clearer image of an object moving fast.

### SUMMARY OF THE INVENTION

An image sensor according to a first aspect of the present invention comprises a carrier generating portion having a photoelectric conversion function, a voltage conversion portion for converting signal charges to a voltage, a charge increasing portion for increasing carriers generated by the carrier generating portion and a light shielding film formed to cover at least one part of the charge increasing portion.

A CMOS image sensor according to a second aspect of the present invention comprises a carrier generating portion having a photoelectric conversion function, a voltage conversion portion for converting signal charges to a voltage, a charge increasing portion for increasing carriers generated by the carrier generating portion and a light shielding film formed to cover at least one part of the charge increasing portion, wherein at least the carrier generating portion, the voltage conversion portion and the charge increasing portion are included in a pixel.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of a CMOS image sensor according to a first embodiment of the present invention;

FIG. 2 is a sectional view showing the structure of the CMOS image sensor according to the first embodiment of the present invention;

FIG. 3 is a plan view showing a pixel in the CMOS image sensor according to the first embodiment of the present invention;

FIG. 4 is a circuit diagram showing a circuit structure of the CMOS image sensor according to the first embodiment of the present invention;

FIG. 5 is a potential diagram for illustrating an electron transferring operation of the CMOS image sensor according to the first embodiment of the present invention;

FIG. 6 is a potential diagram for illustrating an electron multiplying operation of the CMOS image sensor according to the first embodiment of the present invention;

FIG. 7 is a sectional view showing a structure of a CMOS image sensor according to a second embodiment of the present invention;

FIG. 8 is a sectional view showing a structure of a CMOS image sensor according to a third embodiment of the present invention;

FIG. 9 is a sectional view showing a structure of a CMOS image sensor according to a fourth embodiment of the present invention;

FIG. 10 is a sectional view showing a structure of a CMOS image sensor according to a fifth embodiment of the present invention;

FIG. 11 is a sectional view for illustrating an electron multiplying operation of the CMOS image sensor according to the fifth embodiment of the present invention;

FIG. 12 is a sectional view for illustrating a reverse transfer operation of the CMOS image sensor according to the fifth embodiment of the present invention;

FIG. 13 is a sectional view showing a first modification of the CMOS image sensor of the present invention; and

FIG. 14 is a sectional view showing a second modification of the CMOS image sensor of the present invention.

### DESCRIPTION OF THE PREFERRED EMBODIMENTS

Embodiments of the present invention will be hereinafter described with reference to the drawings. Each of the following embodiments of the present invention is applied to an active CMOS image sensor employed as an exemplary image sensor.

### First Embodiment

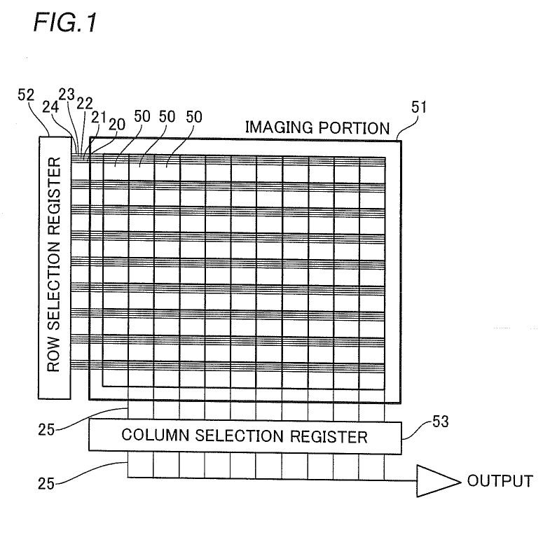

A CMOS image sensor according to a first embodiment comprises an imaging portion 51 including a plurality of pixels 50 arranged in the form of a matrix, a row selection register 52 and a column selection register 53, as shown in FIG. 1.

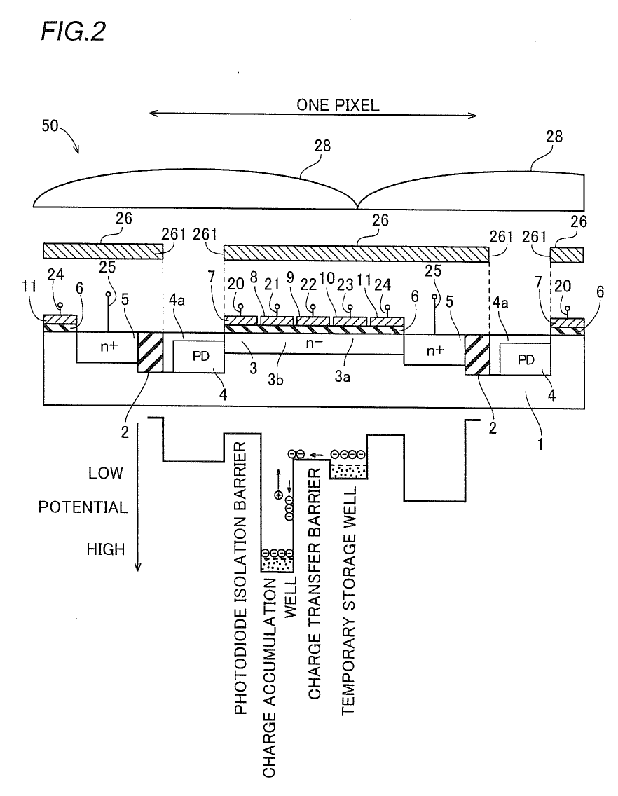

As to the sectional structure of the pixels 50 of the CMOS image sensor according to the first embodiment, element isolation regions 2 for isolating the pixels 50 from each other are formed on the surface of a p-type silicon substrate 1, as shown in FIG. 2. On a surface of the p-type silicon substrate 1 provided with each pixel 50 enclosed with the element isolation region 2, a photodiode (PD) portion 4 and a floating diffusion region 5 consisting of an n⁺-type impurity region are formed at a prescribed interval, to hold a transfer channel 3 consisting of an n⁻-type impurity region therebetween. The photodiode portion 4 is an example of the “carrier generating portion” in the present invention, and the floating diffusion region 5 is an example of the “voltage conversion portion” in the present invention.

The photodiode portion 4 has a function of generating electrons in response to the quantity of incident light and storing the generated electrons. The photodiode portion 4 has a function of generating electrons in response to the quantity of incident light and storing the generated electrons. The photodiode portion 4 is formed to be adjacent to the corresponding element isolation region 2 as well as to the transfer channel 3. A p⁺-type impurity region 4a for suppressing occurrence of a dark current is formed on a surface of the photodiode portion 4 and a side surface of the photodiode portion 4 on a side contact with the element isolation region 2. Thus, the photodiode portion 4 is employed as a buried photodiode.

The floating diffusion region 5 has an impurity concentration (n⁺) higher than the impurity concentration (n⁻) of the transfer channel 3. The floating diffusion region 5 has a function of holding signal charges formed by transferred electrons and converting the signal charges to a voltage. The floating diffusion region 5 is formed to be adjacent to the corresponding element isolation region 2 as well as to the transfer channel 3. Thus, the floating diffusion region 5 is opposed to the photodiode portion 4 through the transfer channel 3.

A gate insulating film 6 is formed on an upper surface of the transfer channel 3. On prescribed regions of an upper surface of the gate insulating film 6, a transfer gate electrode 7, a multiplier gate electrode 8, transfer gate electrodes 9 and 10 and a read gate electrode 11 are formed in this order from the side of the photodiode portion 4 toward the side of the floating diffusion region 5. In other words, the transfer gate electrode 7 is formed to be adjacent to the photodiode portion 4. The transfer gate electrode 7 is formed between the photodiode portion 4 and the transfer gate electrode 8. The transfer gate electrode 9 is formed between the multiplier gate electrode 8 and the transfer gate electrode 10. The multiplier gate electrode 8 is formed on a side opposite to the read gate electrode 11 and the floating diffusion region 5 with respect to the transfer gate electrode 10. The read gate electrode 11 is formed between the transfer gate electrode 10 and the floating diffusion region 5. The read gate electrode 11 is formed to be adjacent to the floating diffusion region 5. The transfer gate electrode 7 is an example of the “first electrode” in the present invention. The multiplier gate electrode 8 is an example of the “second electrode” in the present invention, and the read gate electrode 11 is an example of the “third electrode” in the present invention. The transfer gate electrode 9 is an example of the “fourth electrode” in the present invention. The transfer gate electrode 10 is an example of the “fifth electrode” in the present invention.

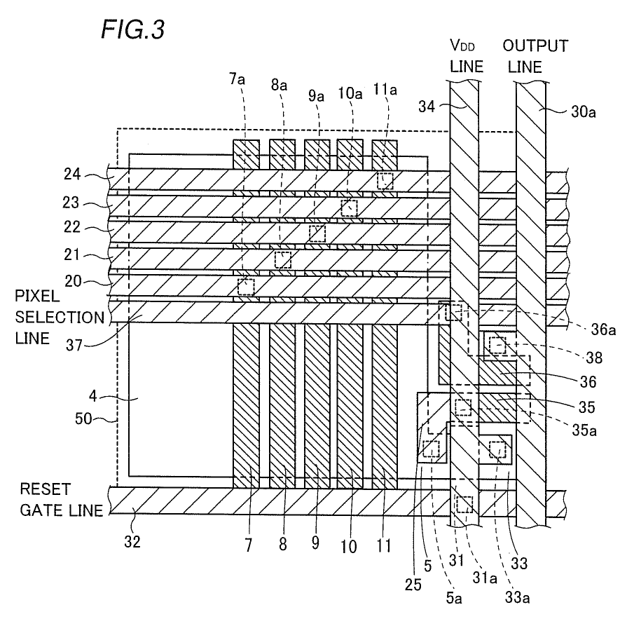

As shown in FIG. 3, wirings 20, 21, 22, 23 and 24 supplying clock signals φ1, φ2, φ3, φ4 and φ5 for voltage control are electrically connected to the transfer gate electrode 7, the multiplier gate electrode 8, the transfer gate electrodes 9 and 10 and the read gate electrode 11 through contact portions 7a, 8a, 9a, 10a and 11a respectively. The wirings 20, 21, 22, 23 and 24 are formed every row, and electrically connected to the transfer gate electrodes 7, the multiplier gate electrodes 8, the transfer gate electrodes 9 and 10 and the read gate electrodes 11 of the plurality of pixels 50 forming each row respectively. A signal line 25 for extracting a signal is electrically connected to each floating diffusion region 5 through a contact portion 5a.

As shown in FIG. 2, the portion (electron storage portion (temporary storage well) 3a) of the transfer channel 3 located under the transfer gate electrode 10 is so formed that an electric field temporarily storing electrons is formed in the portion (electron storage portion 3a) of the transfer channel 3 located under the transfer gate electrode 10 when the ON-state (high-level) clock signal φ4 is supplied to the transfer gate electrode 10.

When the ON-state (high-level) clock signal φ2 is supplied to the multiplier gate electrode 8, the portion (electron multiplying portion (charge accumulation well) 3b) of the transfer channel 3 located under the multiplier gate electrode 8 is controlled to the potential of about 25 V, so that a high electric field impact-ionizing electrons and multiplying (increasing) the number thereof is formed in the portion (electron multiplying portion 3b) of the transfer channel 3 located under the multiplier gate electrode 8. The impact ionization of the electrons is caused on the boundary between the portion (electron multiplying portion 3b) of the transfer channel 3 located under the multiplier gate electrode 8 and the portion of the transfer channel 3 located under the transfer gate electrode 9. The electron multiplying portion 3b is an example of the “charge increasing portion” in the present invention.

The portion of the transfer channel 3 located under the transfer gate electrode 7 has a function of transferring the electrons stored in the photodiode portion 4 to the electron multiplying portion 3b when the ON-state (high-level) clock signal φ1 is supplied to the transfer gate electrode 7, while functioning as a photodiode isolation barrier dividing the photodiode portion 4 and the electron multiplying portion 3b from each other when the OFF-state (low-level) clock signal φ1 is supplied to the transfer gate electrode 7.

The portion of the transfer channel 3 located under the transfer gate electrode 9 has a function of transferring the electrons stored in the electron storage portion 3a to the electron multiplying portion 3b and transferring the electrons stored in the electron multiplying portion 3b to the electron storage portion 3a when the ON-state (high-level) clock signal φ3 is supplied to the transfer gate electrode 9. When the OFF-state (low-level) clock signal φ3 is supplied to the transfer gate electrode 9, on the other hand, the portion of the transfer channel 3 located under the transfer gate electrode 9 functions as a charge transfer barrier dividing the electron storage portion 3a and the electron multiplying portion 3b from each other. In other words, the transfer gate electrode 9 is so supplied with the ON-state (high-level) clock signal φ3 that the electrons stored in the electron storage portion 3a can be transferred to the electron multiplying portion 3b and the electrons stored in the electron multiplying portion 3b can be transferred to the electron storage portion 3a.

The portion of the transfer channel 3 located under the read gate electrode 11 has a function of transferring the electrons stored in the electron storage portion 3a to the floating diffusion region 5 when the ON-state (high-level) clock signal φ5 is supplied to the read gate electrode 11, and a function of dividing the electron storage portion 3a and the floating diffusion region 5 from each other when the OFF-state (low-level) clock signal φ5 is supplied to the read gate electrode 11. In other words, the read gate electrode 11 is so supplied with the ON-state (high-level) clock signal φ5 that the electrons stored in the electron storage portion 3a can be transferred to the floating diffusion region 5.

According to the first embodiment, a light shielding film 26 made of metal such as Al for suppressing incidence of light, having openings 261 is so formed as to cover regions from surfaces of the transfer gate electrodes 7 (surfaces of the transfer gate electrodes 7 in the vicinities of ends of the transfer gate electrodes 7 on the sides of the photodiode portions 4) to surfaces of the element isolation regions 2, as shown in FIG. 2. The electron storage portion 3a provided on each pixel 50 is covered with the light shielding film 26. The light shielding film 26 covering the electron storage portion 3a provided on each pixel 50 may be integrally formed or may be provided independently on each pixel 50. Microlenses 28 are formed above the light shielding film 26. The microlens 28 is provided on each pixel 50 and has a function of condensing light incident on the pixel 50 on the photodiode portion 4 through the opening 261 of the light shielding film 26.

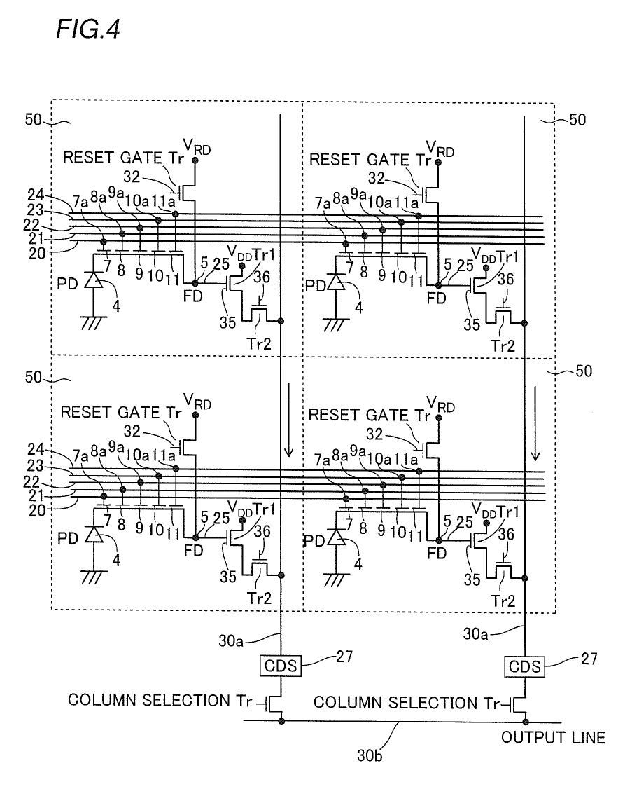

As shown in FIG. 4, a reset gate transistor Tr, an amplification transistor Tr1 and a pixel selection transistor Tr2 connected to the amplification transistor Tr1 for extracting signals every pixel 50 among the plurality of pixels 50 arranged in the form of a matrix are provided on each pixel 50. The reset gate transistor Tr has a function of resetting the voltage of the signal line 25 to a reset voltage VRD (about 5V) after reading, and holding the floating diffusion region 5 electrically floated in reading. A reset signal is supplied to a gate of the reset gate transistor Tr. A reset voltage VRD (about 5V) is applied to a drain of the reset gate transistor Tr. A source of the reset gate transistor Tr is connected to the signal line 25. The signal line 25 is connected to a gate of the amplification transistor Tr1, while a power supply voltage VDD is connected to a drain of the amplification transistor Tr1 and a drain of the pixel selection transistor Tr2 is connected to a source of the amplification transistor Tr1. A source of the pixel selection transistor Tr2 is connected to an output line 30a connected to a first end of the correlated double sampling (CDS) circuit 27. A second end of the correlated double sampling circuit 27 is connected to a drain of a column selection transistor. A source of the column selection transistor is connected to an output line 30b.

As shown in FIG. 3, the reset gate line 32 is connected to a reset gate electrode 31 of the reset gate transistor Tr through a contact portion 31a to be supplied with a reset signal. The drain of the reset gate transistor Tr is connected to a power supply potential (VDD) line 34 through a contact portion 33a. The floating diffusion region 5 constituting the sources of the reset gate transistor Tr and the read gate electrode 11 and a gate electrode 35 of the amplification transistor Tr1 are connected by the signal line 25 through the contact portion 5a and a contact portion 35a. A gate electrode 36 of the pixel selection transistor Tr2 is connected to a pixel selection line 37 through a contact portion 36a and the source of the pixel selection transistor Tr2 is connected to the output line 30a through the contact portion 38.

A read operation of the CMOS image sensor according to the first embodiment will be now described with reference to FIG. 4.

The reset gate transistor Tr of each pixel 50 forming a prescribed row is first brought into an ON-state to reset the potential of the signal line 25. Thereafter the reset pixel selection transistor Tr2 of each reset pixel 50 forming the prescribed row is brought into an ON-state to read a reset level signal to the correlated double sampling circuit 27. Then a high-level signal is supplied to the wire 24 of each reset pixel 50 forming the prescribed row, to bring the read gate electrode 11 of each pixel 50 forming the prescribed one row of the imaging portion 51 into an ON-state. Thus, electrons generated in the photodiode portion 4 of each pixel 50 forming the prescribed one row are read on the signal line 25. Then the pixel selection transistor Tr2 of each reset pixel 50 forming the prescribed row is brought into an ON-state from the this state to read a signal of the photodiode portion 4 on the correlated double sampling circuit 27 through the amplification transistor Tr1 and the pixel selection transistor Tr2. The correlated double sampling circuit 27 samples the both of the reset level signal and the signal of the photodiode portion 4 for performing an operation of subtraction, thereby outputting a signal after removing reset noise. Thereafter the column selection transistors are successively brought into ON-states to output signals of the corresponding respective pixels 50. The CMOS image sensor according to the first embodiment reads data by repeating this operation.

An electron transferring operation of the CMOS image sensor according to the first embodiment of the present invention will be described with reference to FIG. 5.

In a period A shown in FIG. 5, the transfer gate electrode 7 is brought into an ON-state, thereby controlling the portion of the transfer channel 3 located under the transfer gate electrode 7 to a potential of about 4 V. At this time, the photodiode portion 4 is controlled to a potential of about 3 V, and hence electrons generated by and stored in the photodiode portion 4 are transferred from the photodiode portion 4 to the portion of the transfer channel 3 located under the transfer gate electrode 7. Thereafter the multiplier gate electrode 8 is brought into an ON-state to control the portion of the transfer channel 3 located under the multiplier gate electrode 8 to a potential of about 25 V. At this time, the portion of the transfer channel 3 located under the transfer gate electrode 7 is controlled to a potential of about 4 V, and hence the electrons transferred to the portion of the transfer channel 3 located under the transfer gate electrode 7 are transferred to the portion of the transfer channel 3 located under the multiplier gate electrode 8. Thereafter the transfer gate electrode 7 is brought into an OFF-state to control the portion of the transfer channel 3 located under the transfer gate electrode 7 to a potential of about 1 V.

In a period B shown in FIG. 5, the transfer gate electrode 9 is brought into an ON-state and the multiplier gate electrode 8 is brought into an OFF-state to control the portion of the transfer channel 3 located under the transfer gate electrode 9 to a potential of about 4 V to control the portion of the transfer channel 3 located under the multiplier gate electrode 8 to a potential of about 1 V. Thus, the electrons stored in the portion of the transfer channel 3 located under the multiplier gate electrode 8 are transferred to the portion, controlled to a higher potential (about 4 V) than the potential (about 1 V) of the portion of the transfer channel 3 located under the multiplier gate electrode 8, of the transfer channel 3 located under the transfer gate electrode 9.

In a period C shown in FIG. 5, the transfer gate electrode 10 is brought into an ON-state and the transfer gate electrode 9 is brought into an OFF-state to control the portion of the transfer channel 3 located under the transfer gate electrode 10 to a potential of about 4 V and to control the portion of the transfer channel 3 located under the transfer gate electrode 9 to a potential of about 1 V. Therefore, the electrons transferred to the portion of the transfer channel 3 located under the transfer gate electrode 9 are transferred to the portion, controlled to a higher potential (about 4 V) than the potential (about 1 V) of the portion of the transfer channel 3 located under the transfer gate electrode 9, of the transfer channel 3 located under the transfer gate electrode 10. Thus, the electrons transferred from the photodiode portion 4 are temporarily stored in the portion (electron storage portion 3a) of the transfer channel 3 located under the transfer gate electrode 10.

In a period D shown in FIG. 5, the read gate electrode 11 is brought into an ON-state and the transfer gate electrode 10 is brought into an OFF-state while the electrons are temporarily stored in the portion (electron storage portion 3a) of the transfer channel 3 located under the transfer gate electrode 10 to control the portion of the transfer channel 3 located under the read gate electrode 11 to a potential of about 4 V and to control the portion of the transfer channel 3 located under the transfer gate electrode 10 to a potential of about 1 V. Thus, the electrons stored in the portion (electron storage portion 3a) of the transfer channel 3 located under the transfer gate electrode 10 are transferred to the floating diffusion region 5 controlled to a higher potential (about 5V) than the potential (about 1 V) of the portion of the transfer channel 3 located under the transfer gate electrode 10 through the portion of the transfer channel 3 located under the read gate electrode 11 controlled to a potential of about 4V.

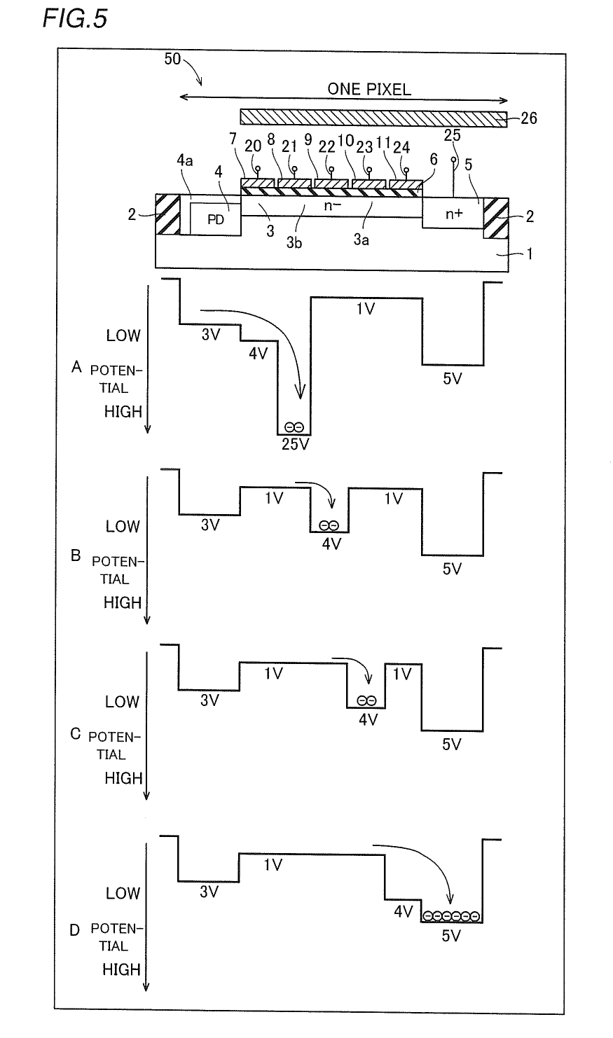

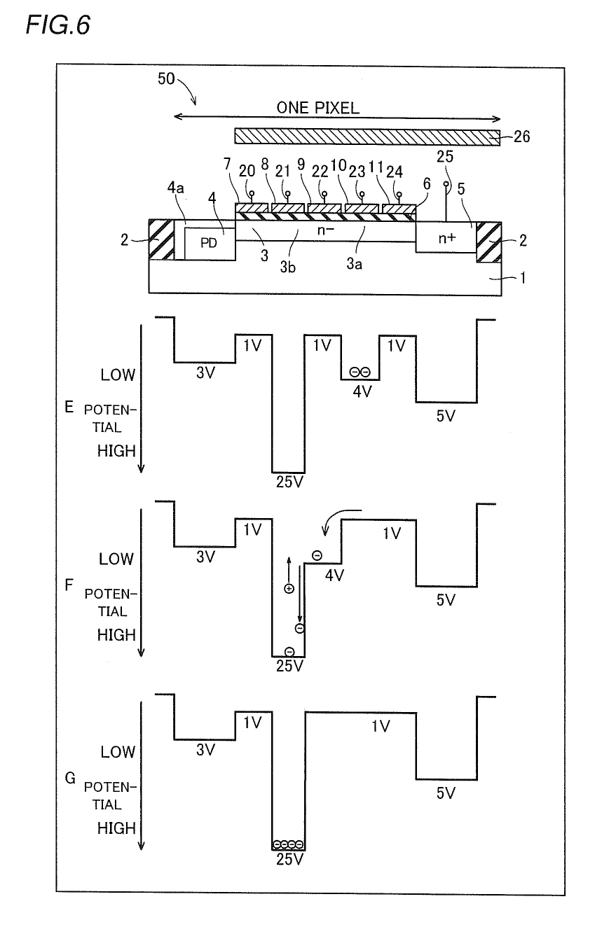

An electron multiplying operation of the CMOS image sensor according to the first embodiment of the present invention will be described with reference to FIG. 6.

In the electron multiplying operation after the transfer operation in the period C shown in FIG. 5, the multiplier gate electrode 8 is brought into an ON-state while the electrons are stored in the portion (electron storage portion 3a) of the transfer channel 3 located under the transfer gate electrode 10 to control the portion (electron multiplying portion 3b) of the transfer channel 3 located under the multiplier gate electrode 8 to a high potential of about 25 V in a period E shown in FIG. 6.

In a period F shown in FIG. 6, the transfer gate electrode 9 is brought into an ON-state and the transfer gate electrode 10 is brought into an OFF-state to control the portion of the transfer channel 3 located under the transfer gate electrode 9 to a potential of about 4 V and to control the portion of the transfer channel 3 located under the transfer gate electrode 10 to a potential of about 1 V. Thus, the electrons stored in the portion of the transfer channel 3 located under the transfer gate electrode 10 are transferred to the portion, controlled to a higher potential (about 4 V) than the potential (about 1 V) of the portion of the transfer channel 3 located under the transfer gate electrode 10, of the transfer channel 3 located under the transfer gate electrode 9. The electrons transferred to the portion of the transfer channel 3 located under the transfer gate electrode 9 are transferred to the portion, controlled to a higher potential (about 25 V) than the potential (about 4 V) of the portion of the transfer channel 3 located under the transfer gate electrode 9, of the transfer channel 3 located under the multiplier gate electrode 8. Then the electrons transferred to the portion (electron multiplying portion 3b) of the transfer channel 3 located under the multiplier gate electrode 8 obtain energy from the high electric field when moving through the boundary between the portion of the transfer channel 3 located under the multiplier gate electrode 8 and the portion of the transfer channel 3 located under the transfer gate electrode 9. The electrons having high energy collide with silicon atoms to generate electrons and holes. Thereafter the electrons generated by impact ionization are stored in the portion (electron multiplying portion 3b) of the transfer channel 3 located under the multiplier gate electrode 8 by the electric field.

In a period G shown in FIG. 6, the transfer gate electrode 9 is brought into an OFF-state to control the portion of the transfer channel 3 located under the transfer gate electrode 9 to a potential of about 1 V.

The CMOS image sensor performs the aforementioned electron transferring operation in the periods B and C shown in FIG. 5, thereby transferring the electrons stored in the portion (electron multiplying portion 3b) of the transfer channel 3 located under the multiplier gate electrode 8 to the portion (electron storage portion 3a) of the transfer channel 3 located under the transfer gate electrode 10. Thereafter the CMOS image sensor repeats the multiplying operation in the periods E to G and the transferring operation in the periods B and C a plurality of times (about 400 times, for example), thereby multiplying the electrons transferred to the photodiode portion 4 to about 2000 times. Thus, the electrons are transferred between the portion of the transfer channel 3 located under the multiplier gate electrode 8 and the portion of the transfer channel 3 located under the transfer gate electrode 10 through the portion of the transfer channel 3 located under the transfer gate electrodes 9, surfaces of which are covered by the light shielding film 26, to multiply the electrons, according to the first embodiment.

The electrons are stored in the portion (electron multiplying portion 3b) of the transfer channel 3 located under the multiplier gate electrode 8 of each pixel 50 after completing the electron multiplying operation. Thereafter the electrons are read on the floating diffusion regions 5 every row of the pixels 50 arranged in the form of matrix. In other words, the electrons before reading are stored in the portion (electron multiplying portion 3b) of the transfer channel 3 located under the multiplier gate electrode 8, according to the first embodiment.

According to the first embodiment, as hereinabove described, the CMOS image sensor comprises the electron multiplying portions 3b for multiplying the electrons generated by the photodiode portions 4 and the light shielding film 26 formed to cover the surfaces of the electron multiplying portions 3b, whereby incidence of light upon the electron multiplying portions 3b can be suppressed during the electron multiplying operation, and hence influence of light incident upon the electron multiplying portion 3b (noise caused by electrons newly generated by photoelectric conversion) can be suppressed even when the time period of the electron multiplying operation is increased. Thus, it can take a long time to multiply electrons stored for a short imaging period, and hence the speed of a shutter can be increased while enhancing the sensitivity of the image sensor.

According to the first embodiment, as hereinabove described, the light shielding film 26 are formed to cover the region from the surfaces of the transfer gate electrodes 7 to surfaces of the floating diffusion regions 5 (element isolation region 2), whereby incidence of external light upon the electron multiplying portion 3b can be further suppressed during the electron multiplying operation, and hence noise caused by the external light incident upon the electron multiplying portion 3b can be further suppressed even when the time period of the electron multiplying operation can be increased.

According to the first embodiment, as hereinabove described, the floating diffusion regions 5 are provided on the plurality of the pixels 50 respectively and the light shielding film 26 is so formed as to cover the electron multiplying portions 3b provided on the plurality of the pixels 50 respectively, so that the CMOS image sensor can be formed.

According to the first embodiment, as hereinabove described, the CMOS image sensor is so formed as to store the electrons before being read on the floating diffusion regions 5 are stored in the electron multiplying portions 3b, whereby the light shielding film 26 covers the electron multiplying portions 3b, and hence noise caused by external light can be suppressed until the electrons are read on the floating diffusion regions 5. Thus, the electrons may not be reset every reading, and hence global shutter performing reset of the electrons stored in all of the pixels and start of storage of the electrons simultaneously can be achieved.

### Second Embodiment

In a structure of a CMOS image sensor according to a second embodiment, transfer gate electrodes 7 are partially covered with a light shielding film 26a dissimilarly to the aforementioned first embodiment.

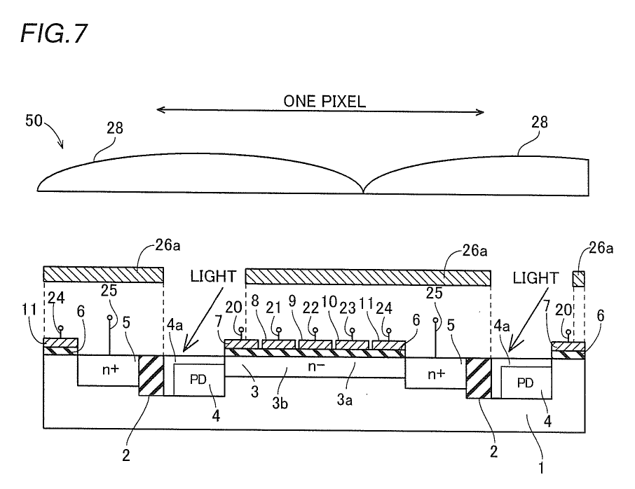

The CMOS image sensor according to the second embodiment is so formed that the light shielding film 26a made of metal such as Al for suppressing incidence of light is formed to cover a region from a partial surface of each transfer gate electrode 7 on a side of a corresponding multiplier gate electrode 8 to a surface of each of element isolation regions 2 as shown in FIG. 7.

The remaining structure and operation of the CMOS image sensor according to the second embodiment are similar to the aforementioned first embodiment.

According to the second embodiment, as hereinabove described, the light shielding film 26a is so formed as to cover the region from the partial surface of each transfer gate electrode 7 on the side of the corresponding multiplier gate electrode 8 to the surface of each of element isolation regions 2, whereby the partial surface of each transfer gate electrode 7 does not block light and hence light can be obliquely incident upon the photodiode portion 4 from the side of the multiplier gate electrode 8. Thus, the sensitivity of the image sensor can be enhanced.

The remaining effects of the aforementioned second embodiment are similar to those of the aforementioned first embodiment.

### Third Embodiment

In a CMOS image sensor according to a third embodiment, four layers of light shielding films 26, 26c, 26d and 26e are formed dissimilarly to the aforementioned first embodiment.

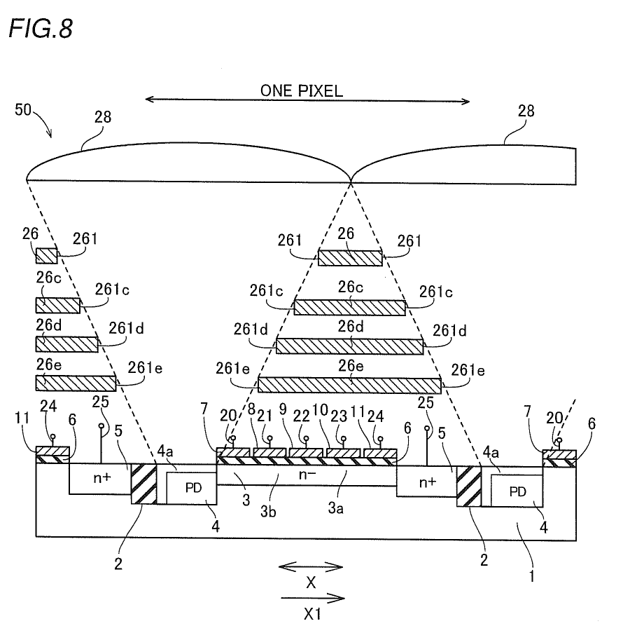

The CMOS image sensor according to the third embodiment is so arranged as to stack four layers of the light shielding films 26, 26c, 26d and 26e between transfer gate electrodes 7, multiplier gate electrodes 8, transfer gate electrodes 9 and 10 and read gate electrodes 11 and microlenses 28 in a vertical direction as shown in FIG. 8. The four layers of the light shielding films 26 and 26c to 26e have openings 261, 261c, 261d and 261e on positions corresponding to the photodiode portions 4 respectively. The light shielding film 26e arranged on a lower portion among four layers of the light shielding films 26 and 26c to 26e is so formed as to cover the electron multiplying portions 3b. The respective ends of the four layers of the light shielding films 26 and 26c to 26e are arranged in the vicinities of lines connecting ends of the photodiode portions 4 in a electron transfer direction (along arrow X1) and ends of microlenses 28 in the electron transfer direction (along arrow X1). The four layers of the light shielding films 26 and 26c to 26e may be so arranged in the vicinity of light flux guided to each photodiode portion 4 by the microlens 28 that the respective ends of the four layers of the light shielding films 26 and 26c to 26e do not block the light flux.

According to the third embodiment, the openings of the light shielding film arranged on the upper portion among the four layers of the light shielding films 26 and 26c to 26e are formed to be larger than the openings of the light shielding film arranged on the lower portion among the four layers of the light shielding films 26 and 26c to 26e. In other words, the sizes of the openings 261e, 261d, 261c and 261 are increased in this order. Thus, incidence of light upon each electron multiplying portion 3b can be suppressed without blocking collection of light incident upon the light shielding film. The length of the light shielding film arranged on the upper portion among the four layers of the light shielding films 26 and 26c to 26e in the direction (along arrow X) along the electron transfer direction are formed to be smaller than that of the light shielding film arranged on the lower portion among the four layers of the light shielding films 26 and 26c to 26e in the direction (along arrow X) along the electron transfer direction.

The remaining structure and operation of the CMOS image sensor according to the third embodiment are similar to those of the CMOS image sensor according to the aforementioned first embodiment.

According to the third embodiment, as hereinabove described, the openings of the light shielding film arranged on the upper portion among the four layers of the light shielding films 26 and 26c to 26e are formed to be larger than the openings of the light shielding film arranged on the lower portion among the four layers of the light shielding films 26 and 26c to 26e, whereby the light shielding films do not block light incident through each microlens 28 and hence reduction in light condensing performance of each photodiode portion 4 can be suppressed.

The remaining effects of the third embodiment are similar to those of the aforementioned first embodiment.

### Fourth Embodiment

In a CMOS image sensor according to a fourth embodiment with the structure of the CMOS image sensor according to the aforementioned third embodiment, the centers of microlenses 28 and the centers of photodiode portions 4 are so arranged as to deviate from each other.

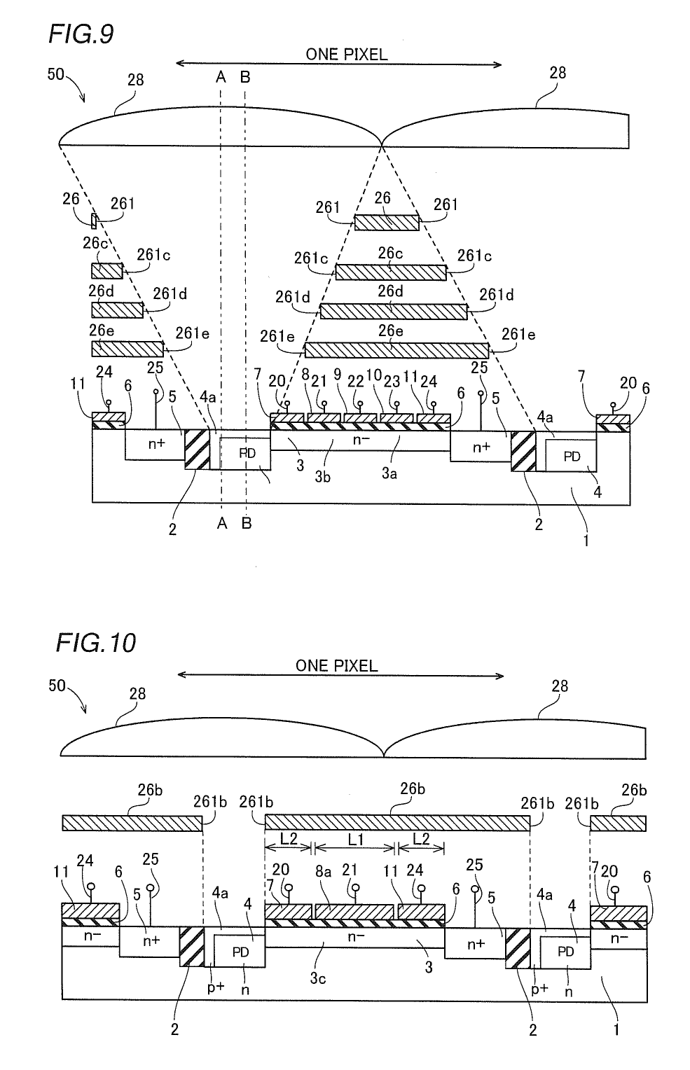

In the CMOS image sensor according to the fourth embodiment, the center (centerline A-A) of the microlens 28 in each pixel 50 arranged on sides of ends of an imaging portion 51 (see FIG. 1) is so arranged to be deviated to a side of the end with respect to the center (centerline B-B) of the photodiode portion 4, as shown in FIG. 9. When the center (centerline A-A) of each microlens 28 is deviated with respect to the center of the photodiode portion 4, the light shielding films 26 and 26c to 26e are also arranged to be deviated in response to position of each microlens 28 so that light shielding films 26 and 26c to 26e do not block collection of light by the microlens 28. Thus, blocking of light incident through each microlens 28 can be suppressed and hence light condensing performance of each photodiode portion 4 can be improved.

The remaining structure and operation of the CMOS image sensor according to the fourth embodiment are similar to those of the CMOS image sensor according to the aforementioned third embodiment.

The remaining effects of the fourth embodiment are similar to those of the aforementioned third embodiment.

### Fifth Embodiment

In a structure of a CMOS image sensor according to a fifth embodiment, an electron multiplying operation is performed between photodiode portions 4 and portions of transfer channels 3 located under multiplier gate electrodes 8a through portions of the transfer channels 3 located under transfer gate electrodes 7 dissimilarly to the aforementioned first embodiment.

In the CMOS image sensor according to the fifth embodiment, element isolation regions 2 for isolating pixels 50 from each other are formed on a surface of a p-type silicon substrate 1, as shown in FIG. 10. The photodiode portion 4 and a floating diffusion region 5 consisting of an n⁺-type impurity region are formed at a prescribed interval on the surface of the p-type silicon substrate 1 provided with each pixel 50 enclosed with the element isolation region 2, to hold the transfer channel 3 consisting of an n⁻-type impurity region therebetween. The photodiode portion 4 is an example of the “carrier generating portion” in the present invention and the floating diffusion region 5 is an example of the “voltage conversion portion” in the present invention.

A gate insulating film 6 is formed on an upper surface of the transfer channel 3. On prescribed regions of an upper surface of the gate insulating film 6, the transfer gate electrode 7, the multiplier gate electrode 8a, the read gate electrode 11 are formed in this order from a side of the photodiode portion 4 toward a side of the floating diffusion region 5. In other words, transfer gate electrode 7 is formed to be adjacent to the photodiode portion 4. The transfer gate electrode 7 is formed between the photodiode portion 4 and the multiplier gate electrode 8a. The read gate electrode 11 is formed to be adjacent to the floating diffusion region 5. The multiplier gate electrode 8a is an example of the “second electrode” in the present invention.

A gate length L1 of the multiplier gate electrode 8a in an electron transfer direction is formed to be larger than gate lengths L2 of the transfer gate electrode 7 and the read gate electrode 11. Thus, a larger number of electrons can be stored in a portion of the transfer channel 3 located under the multiplier gate electrode 8a dissimilarly to a case where the gate length L1 of the multiplier gate electrode 8a in the electron transfer direction and the gate lengths L2 of the transfer gate electrode 7 and the read gate electrode 11 are equal. The gate length L1 of the multiplier gate electrode 8a in the electron transfer direction and the gate lengths L2 of the transfer gate electrode 7 and the read gate electrode 11 may be equal.

According to the fifth embodiment, a light shielding film 26b made of metal such as Al for suppressing incidence of light is so formed as to cover regions from surfaces of the transfer gate electrodes 7 to surfaces of the element isolation regions 2, as shown in FIG. 10. Microlenses 28 are formed above the light shielding film 26b. The microlens 28 is provided on each pixel 50 and has a function of condensing light incident on the pixel 50 on the photodiode portion 4 through an opening 261b of the light shielding film 26b. A plurality of layers of light shielding films may be formed between the transfer gate electrode 7, the multiplier gate electrode 8a and the read gate electrode 11 and the light shielding film 26b similarly to the aforementioned third and fourth embodiments.

The transfer gate electrode 7, the multiplier gate electrode 8a and the read gate electrode 11 are supplied with ON-state (high-level) clock signals, thereby applying voltages of about 2.9 V to the transfer gate electrode 7 and the read gate electrode 11 and applying a voltage of about 24 V to the multiplier gate electrode 8a. Thus, the portion of the transfer channel 3 located under the transfer gate electrode 7 and the portion of the transfer channel 3 located under the read gate electrode 11 are controlled to potentials of about 4 V. The portion of the transfer channel 3 located under the multiplier gate electrode 8a are controlled to a higher potential of about 25 V. The portion of the transfer channel 3 located under the transfer gate electrode 7, the portion of the transfer channel 3 located under the multiplier gate electrode 8a and the portion of the transfer channel 3 located under the read gate electrode 11 are controlled to potentials of about 1 V while supplying OFF-state (low-level) clock signals thereto. The photodiode portion 4 and the floating diffusion region 5 are controlled to potentials of about 3 V and about 5 V respectively.

When the ON-state (high-level) signal is supplied to the multiplier gate electrode 8a, the portion (electron multiplying portion 3c) of the transfer channel 3 located under the multiplier gate electrode 8 is controlled to the potential of about 25 V, so that a high electric field impact-ionizing electrons and multiplying (increasing) the number thereof is formed in the portion (electron multiplying portion 3c) of the transfer channel 3 located under the multiplier gate electrode 8a. The impact ionization of the electrons is caused on the boundary between the portion (electron multiplying portion 3c) of the transfer channel 3 located under the multiplier gate electrode 8 and the portion of the transfer channel 3 located under the transfer gate electrode 7. The electron multiplying portion 3c is an example of the “charge increasing portion” in the present invention.

The remaining structure of the CMOS image sensor according to the fifth embodiment is similar to that of the CMOS image sensor according to the aforementioned first embodiment.

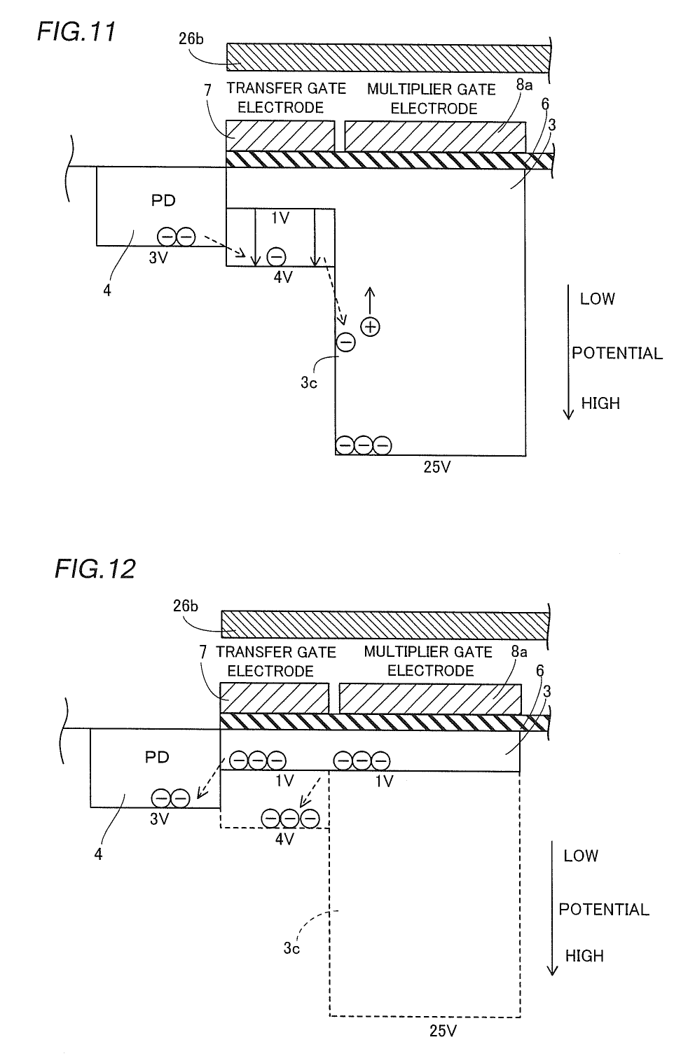

An electron multiplying operation of the CMOS image sensor according to the fifth embodiment of the present invention will be described with reference to FIG. 11.

As shown in FIG. 11, when light is incident upon the photodiode portion 4, electrons are generated in the photodiode portion 4 by photoelectric conversion. Then the multiplier gate electrode 8a is brought into an ON-state while the transfer gate electrode 7 is kept in an OFF-state, thereby controlling a potential of the portion of the transfer channel 3 located under the multiplier gate electrode 8a to a potential of about 25V. At this time, the portion of the transfer channel 3 located under the transfer gate electrode 7 is controlled to a potential of about 1 V. The photodiode portion 4 is controlled to a potential of about 3V, and hence the generated electrons are not transferred to the portion, having a potential lower than that of the photodiode portion 4, of the transfer channel 3 located under the transfer gate electrode 7, but stored in the photodiode portion 4.

Then the transfer gate electrode 7 is brought into an ON-state while the multiplier gate electrode 8a is kept in an ON-state. In other words, the portion of the transfer channel 3 located under the transfer gate electrode 7 is controlled to a potential of about 4 V while controlling the portion of the transfer channel 3 located under the multiplier gate electrode 8a to a potential of about 25 V. Thus, electrons stored in the photodiode portion 4 are transferred to the portion, controlled to a higher potential (about 4 V) than the potential (about 3 V) of the photodiode portion 4, of the transfer channel 3 located under the transfer gate electrode 7, and the electrons transferred to the portion of the transfer channel 3 located under the transfer gate electrode 7 are transferred to the portion, controlled to a further higher potential (about 25 V) than a potential (about 4 V) of the portion of the transfer channel 3 located under the transfer gate electrode 7, of the transfer channel 3 located under the multiplier gate electrode 8a. At this time, the electrons transferred from the portion of the transfer channel 3 located under the transfer gate electrode 7 to the portion of the transfer channel 3 located under the multiplier gate electrode 8a obtain energy from the high electric field when moving through the boundary between the portions of the transfer channel 3 located under the transfer gate electrode 7 and the multiplier gate electrode 8a. Then the electrons having high energy collide with silicon atoms to generate electrons and holes (impact ionization). Thereafter the electrons generated by impact ionization are stored in the portion of the transfer channel 3 located under the multiplier gate electrode 8a by electric field.

A reverse transfer operation of the CMOS image sensor according to the fifth embodiment of the present invention will be now described with reference to FIG. 12.

First, the transfer gate electrode 7 is kept in an ON-state and the multiplier gate electrode 8a is brought into an OFF-state. Thus, the portion of the transfer channel 3 located under the multiplier gate electrode 8a is controlled to a potential of about 1 V while controlling the portion of the transfer channel 3 located under the transfer gate electrode 7 to a potential of about 4 V as shown in FIG. 12. Thus, electrons stored in the portion of the transfer channel 3 located under the multiplier gate electrode 8a are transferred to the portion, controlled to a higher potential (about 4 V) than the potential (about 1 V) of the portion of the transfer channel 3 located under the multiplier gate electrode 8a, of the transfer channel 3 located under the transfer gate electrode 7. The multiplier gate electrode 8a is kept in an OFF-state and the transfer gate electrode 7 is also brought into an OFF-state. Thus, the portion of the transfer channel 3 located under the transfer gate electrode 7 is controlled to a potential of about 1 V identical to the potential of the portion of the transfer channel 3 located under the multiplier gate electrode 8a from a state of being controlled to a potential of about 4 V while controlling the portion of the transfer channel 3 located under the multiplier gate electrode 8a to a potential of about 1 V. The photodiode portion 4 is controlled to a higher potential (about 3 V) than potentials (about 1 V) of the portions of the transfer channel 3 located under the transfer gate electrode 7 and the multiplier gate electrode 8a. Therefore, the electrons transferred to the portion of the transfer channel 3 located under the transfer gate electrode 7 are transferred to the photodiode portion 4 controlled to a further higher potential. Thus, the electrons stored in the portion of the transfer channel 3 located under the multiplier gate electrode 8a are transferred to the photodiode portion 4. Then the electrons transferred to the photodiode portion 4 are transferred from the photodiode portion 4 to the portion of the transfer channel 3 located under the multiplier gate electrode 8a by the aforementioned multiplying operation again, and the aforementioned multiplying operation and the aforementioned reverse transfer operation are repeated. The multiplied electrons are stored in the portion of the transfer channel 3 located under the multiplier gate electrode 8a as a charge signal. Thereafter signal charges are read as a voltage signal through the floating diffusion region 5 and the signal line 25 similarly to the aforementioned read operation of the first embodiment.

The effects of the fifth embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the three or five gate electrodes are provided in the one pixel of the image sensor in each of the aforementioned embodiments, the present invention is not restricted to this but the present invention may be applied to an image sensor provided with gate electrodes other than 3 or 5 gate electrodes so far as the image sensor performs the electron multiplying operation.

While the image sensor is formed on the p-type silicon substrate in each of the aforementioned embodiments, the present invention is not restricted to this but a p-type impurity diffusion region formed on an n-type silicon substrate may be employed as a substrate.

While the electrons are employed as carriers in each of the aforementioned embodiments, the present invention is not restricted to this but holes may alternatively be employed as the carriers by entirely reversing the conductivity type of the substrate impurity and the polarities of the applied voltages.

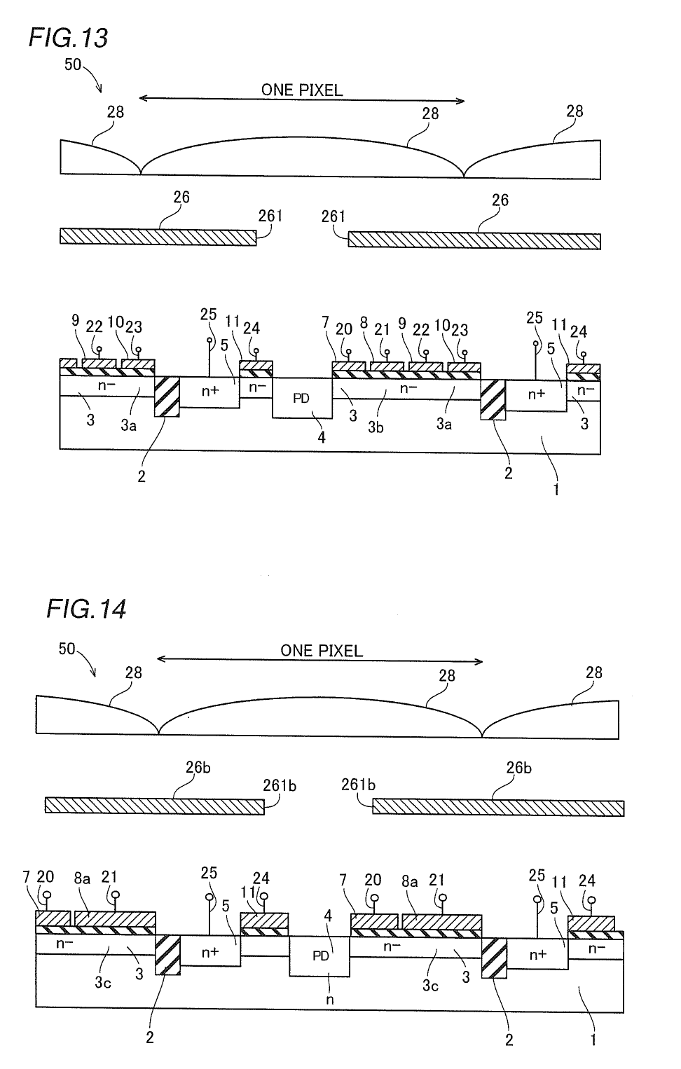

While the electron multiplying operation is formed between the photodiode portion and the floating diffusion region in each of the aforementioned embodiments, the present invention is not restricted to this but the photodiode portion 4 may be provided between the electron multiplying portion 3b and the floating diffusion region 5 as shown in FIG. 13. In this case, electrons are multiplied between the portion of the transfer channel 3 located under the multiplier gate electrode 8 and the portion of the transfer channel 3 located under the transfer gate electrode 10. As shown in FIG. 14, the photodiode portion 4 may be provided between the electron multiplying portion 3b and the floating diffusion region 5 and electrons may be multiplied between the photodiode portion 4 and the portion of the transfer channel 3 located under the multiplier gate electrode 8.

While the plurality of layers of light shielding films are formed from the four layers of light shielding film in each of the aforementioned third and fourth embodiments, the present invention is not restricted to this but a plurality of layers of light shielding films may be formed from the plurality of layers other than the four layers of light shielding films.

What is claimed is:

1. An image sensor comprising:
a carrier generating portion having a photoelectric conversion function;
a voltage conversion portion for converting signal charges to a voltage;
a charge increasing portion for increasing carriers generated by said carrier generating portion; and
a light shielding film formed to cover at least one part of said charge increasing portion.

2. The image sensor according to claim 1, wherein
said light shielding film is formed to entirely cover said charge increasing portion.

3. The image sensor according to claim 1, further comprising:
a first electrode arranged to be adjacent to said carrier generating portion; and
a second electrode for generating an electric field impact-ionizing the carriers in said charge increasing portion, arranged on a region corresponding to said charge increasing portion on a side of said first electrode opposite to said carrier generating portion, wherein
said light shielding film is so formed as to cover at least a partial surface of said first electrode on a side of said second electrode and said second electrode.

4. The image sensor according to claim 3, wherein
said first electrode and said second electrode are provided between said carrier generating portion and said voltage conversion portion,
further comprising a third electrode for reading the carriers on said voltage conversion portion, provided between said second electrode and said voltage conversion portion, wherein
said light shielding film is so formed as to cover a region from at least said partial surface of said first electrode on the side of said second electrode to a surface of said third electrode and a surface of said voltage conversion portion.

5. The image sensor according to claim 4, further comprising a fourth electrode for applying a voltage forming a carrier transfer barrier provided between said second electrode and said third electrode and a fifth electrode applying a voltage for storing the carriers, wherein
said light shielding film is so formed as to cover at least one part of said first electrode on the side of said second electrode, said second electrode, said third electrode, said fourth electrode, said fifth electrode and said voltage conversion portion.

6. The image sensor according to claim 4, wherein
said light shielding film is so formed as to cover a region from the surface of said first electrode in the vicinity of an end of said first electrode on a side of said carrier generating portion to said surface of said third electrode and said surface of said voltage conversion portion.

7. The image sensor according to claim 6, further comprising an element isolation region provided to be adjacent to a side of said voltage conversion portion in a carrier transfer direction, wherein
said light shielding film is so formed as to cover a region from said surface of said first electrode in the vicinity of said end of said first electrode on the side of said carrier generating portion to a surface of said element isolation region.

8. The image sensor according to claim 3, wherein
said voltage conversion portion is provided on the side of said first electrode opposite to the side of said carrier generating portion,
further comprising a third electrode for reading the carriers on said voltage conversion portion, provided between said carrier generating portion and said voltage conversion portion, wherein
said light shielding film is so formed as to cover at least one part of said first electrode on the side of said second electrode and said second electrode as well as at least one part of said third electrode on a side of said voltage conversion portion and said voltage conversion portion.

9. The image sensor according to claim 1, further comprising a plurality of pixels, wherein
said charge increasing portions are provided on said plurality of pixels respectively, and said light shielding film is so formed as to cover said charge increasing portions provided on said plurality of pixels respectively.

10. The image sensor according to claim 1, further comprising a plurality of pixels, wherein
said plurality of pixels include said carrier generating portions and said voltage conversion portions respectively, and
carriers before being read on said voltage conversion portions are stored in said charge increasing portions.

11. The image sensor according to claim 1, wherein
said light shielding film is configured of a plurality of layers of light shielding films having openings on positions corresponding to said carrier generating portion respectively and stacked in a vertical direction, and
said opening of at least one said light shielding film arranged on an upper portion among said plurality of layers of light shielding films is formed to be larger than said opening of at least one said light shielding film arranged on a lower portion among said plurality of layers of light shielding films.

12. The image sensor according to claim 11, wherein
at least said light shielding film arranged on the lower portion among said plurality of layers of light shielding films is so formed as to cover at least the one part of said charge increasing portion.

13. The image sensor according to claim 11, wherein
a length of said light shielding film arranged on the upper portion among said plurality of layers of light shielding films in a direction along a carrier transfer direction is formed to be smaller than a length of said light shielding film arranged on the lower portion among said plurality of layers of light shielding films in the direction along the carrier transfer direction.

14. The image sensor according to claim 11, further comprising a microlens provided to be opposed to said carrier generating portion,
wherein said plurality of layers of light shielding films are so arranged in the vicinity of light flux guided to said carrier generating portion by said microlens that respective ends of said plurality of layers of light shielding films do not block the light flux.

15. The image sensor according to claim 11, further comprising:
an imaging portion arranged with a plurality of pixels in the form of matrix; and
microlenses provided to be opposed to said carrier generating portions of said pixels, wherein
in said pixel arranged in the vicinity of an end of said imaging portion, a center of said microlens in a direction along a carrier transfer direction is deviated to a side of said end of said imaging portion with respect to a center of said carrier generating portion in the direction along the carrier transfer direction, and centers of said openings of said plurality of layers of light shielding films in the direction along the carrier transfer direction is deviated to the side of said end of said imaging portion with respect to the center of said carrier generating portion in the direction along the carrier transfer direction.

16. A CMOS image sensor comprising:
a carrier generating portion having a photoelectric conversion function;
a voltage conversion portion for converting signal charges to a voltage;
a charge increasing portion for increasing carriers generated by said carrier generating portion; and
a light shielding film formed to cover at least one part of said charge increasing portion, wherein
at least said carrier generating portion, said voltage conversion portion and said charge increasing portion are included in a pixel.

17. The CMOS image sensor according to claim 16, wherein
said light shielding film is so formed as to entirely cover said charge increasing portion.

18. The CMOS image sensor according to claim 16, further comprising:
a first electrode arranged to be adjacent to said carrier generating portion; and
a second electrode for generating an electric field impact-ionizing the carriers in said charge increasing portion, arranged on a region corresponding to said charge increasing portion on a side of said first electrode opposite to said carrier generating portion, wherein
said light shielding film is so formed as to cover at least a partial surface of said first electrode on a side of said second electrode and said second electrode.

19. The CMOS image sensor according to claim 18, wherein
said first electrode and said second electrode are provided between said carrier generating portion and said voltage conversion portion,
further comprising a third electrode for reading the carriers on said voltage conversion portion, provided between said second electrode and said voltage conversion portion, wherein
said light shielding film is so formed as to cover a region from at least said partial surface of said first electrode on the side of said second electrode to a surface of said third electrode and a surface of said voltage conversion portion.

20. The CMOS image sensor according to claim 16, wherein
said light shielding film is configured of a plurality of layers of light shielding films having openings on positions corresponding to said carrier generating portion respectively and stacked in a vertical direction, and
said opening of said light shielding film arranged on an upper portion among said plurality of layers of light shielding films is formed to be larger than said opening of said light shielding film arranged on a lower portion among said plurality of layers of light shielding films.
